(19) United States
(12) Patent Application Publication
(10) Pub. No.: US 2016/0260606 A1
(43) Pub. Date: Sep. 8, 2016

(54) METHODS OF FORMING A MASKING PATTERN AND A SEMICONDUCTOR DEVICE STRUCTURE

(71) Applicant: GLOBALFOUNDRIES Inc., Grand Cayman (KY)

(72) Inventors: Hans-Peter Moll, Dresden (DE); Peter Baars, Dresden (DE)

(21) Appl. No.: 14/635,071

(22) Filed: Mar. 2, 2015

(51) Int. Cl. H01L 21/033; H01L 29/417; H01L 29/78

(52) U.S. Cl. CPC H01L 21/0338; H01L 29/78; H01L 29/41775; H01L 21/0332; H01L 21/0335; H01L 21/0337

(57) ABSTRACT

The present disclosure provides methods of forming a masking pattern and a semiconductor device structure, wherein printed half pitches of, for example, about 20 nm or less may be formed. A method of forming a masking pattern is provided wherein an unpatterned mask layer is formed over a semiconductor device structure provided in and on an upper surface of a semiconductor substrate, and the unpatterned mask layer is patterned for forming the masking pattern over the semiconductor device structure. The unpatterned mask layer is patterned by forming a dummy pattern having at least one recess on the unpatterned mask layer, forming a first sidewall spacer structure adjacent to sidewalls of the recess, removing the dummy pattern, forming a second sidewall spacer structure on the first sidewall spacer structure, removing the first sidewall spacer structure, and etching the unpatterned mask layer in alignment with the second sidewall spacer structure.

### BACKGROUND OF THE INVENTION

1. Field of the Invention

The present disclosure generally relates to methods of forming a masking pattern and to a semiconductor device structure and, more particularly, to the formation of masking patterns enabling sub-nominal lines/spaces and contact patterns for advanced semiconductor device structures, e.g., memory cell arrays.

2. Description of the Related Art

In modern electronic equipment, integrated circuits (ICs) experience a vast applicability in a continuously spreading range of applications. In particular, the demand for increasing mobility of electronic devices at high performance and low energy consumption drives developments to more and more compact devices having features with sizes significantly smaller than 1 μm, the more so as current semiconductor technologies are apt of producing structures with dimensions in the magnitude of 100 nm or less. With ICs representing a set of electronic circuit elements integrated on a semiconductor material, normally silicon, ICs may be made much smaller than any discreet circuit composed of separate independent circuit components. Indeed, the majority of present-day ICs are implemented by using a plurality of circuit elements, such as field effect transistors (FETs), also called metal oxide semiconductor field effect transistors or MOSFETs, occasionally also simply referred to as MOS transistors, and passive elements, such as resistors, e.g., diffusion resistors, and capacitors, integrated on a semiconductor substrate within a given surface area. Typical present-day ICs involve millions of single circuit elements formed on a semiconductor substrate.

The basic function of a MOSFET is that of an electronic switching element, controlling a current through a channel region provided between two junction regions which are referred to as source and drain. The control of the conductivity state of the channel region is achieved by means of a gate electrode being disposed over the channel region and to which gate electrode a voltage relative to source and drain is applied. In common planar MOSFETs, the channel region extends in a plane between source and drain. Generally, in applying a voltage exceeding a characteristic voltage level to the gate electrode, the conductivity state of the channel is changed and switching between a conducting state or “ON-state” and a non-conducting state or “OFF-state” may be achieved. It is important to note that the characteristic voltage level at which the conductivity state changes (usually called the “threshold voltage”) therefore characterizes the switching behavior of the MOSFET and it is generally an issue to keep variations in the threshold voltage level low when implementing a desired switching characteristic. However, with the threshold voltage depending nontrivially on the transistor's properties, e.g., materials, dimensions, etc., the implementation of a desired threshold voltage value during fabrication processes involves careful adjustment and fine tuning during the fabrication processes, which makes the fabrication of complex semiconductor devices by advanced technologies more and more difficult.

At present, the scaling of semiconductor devices down to smaller sizes follows so-called Moore's Law according to which the number of transistors in a dense integrated circuit doubles approximately every two years. Originally intended as a prediction to describe the trend of the development of computing hardware in an article by Gordon Moore in 1965, Moore's Law became a long-term guide which the semiconductor industry follows as a roadmap for planning and setting targets in research and development of advanced semiconductor devices. Until today, Moore's Law drives the scaling of semiconductor devices and structures down to continuously decreasing sizes.

The continued scaling constantly raised new challenges which are met by increasingly complex technical solutions developed in the art. For example, patterning small parts of a thin film or the bulk of a substrate at advanced technology nodes has been achieved by photolithography, which became an important technique used in micro fabrication processes. In photolithography, an image is projected onto a substrate by one or more optical masks via a light sensitive chemical photoresist deposited on the substrate. Then, a series of chemical treatments either engraves the exposure pattern into, or enables the position of a new material in the desired pattern upon, the material underneath the photoresist. However, the continued scaling following Moore's Law has led, at present, to the issue of printing half pitches of about 20 nm or less. As contemporary photolithographical techniques do not allow printing of such small pitches, a satisfactory solution does not exist in the art.

It is, therefore, desirable to provide for methods of forming a masking pattern that complies with a lithography roadmap to continue the scaling of integrated circuit structures down to smaller technology scales in accordance with Moore's Law. Furthermore, it is desirable to provide a semiconductor device structure that has a printed half pitch of about 20 nm or less.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In various aspects, the present disclosure provides for methods of forming a masking pattern and a semiconductor device structure, wherein printed half pitches of dimensions which are substantially smaller than a minimum feature size that may be reached by known lithography techniques and/or known lithography tools may be formed, such as, for example, dimensions of about 24 nm or less.

According to a first aspect of the present disclosure, a method of forming a masking pattern is provided. In accordance with some illustrative embodiments herein, the method comprises forming an unpatterned mask layer over a semiconductor device structure provided in and on an upper surface of a semiconductor substrate, and patterning the unpatterned mask layer for forming the masking pattern over the semiconductor device structure. Herein, the unpatterned mask layer is patterned by forming a dummy pattern on the unpatterned mask layer, wherein the dummy pattern has at least one recess, forming a first sidewall spacer structure adjacent to sidewalls of the at least one recess, wherein a first width dimension of the first sidewall spacer structure is smaller than half a width of the recess, removing the dummy pattern while maintaining the first sidewall spacer structure over the unpatterned mask layer, forming a second sidewall spacer structure on the first sidewall spacer structure, wherein a second width dimension of the second sidewall spacer structure is smaller than half the width of the recess, removing the first sidewall spacer structure while maintaining the second sidewall spacer structure over the unpatterned mask layer, and etching the unpatterned mask layer in alignment with the second sidewall spacer structure.

In a second aspect of the present disclosure, a method of forming a masking pattern having a minimum size that is substantially smaller than a minimum feature size (F) to be reached by lithography techniques is provided. In accordance with some illustrative embodiments herein, the method includes forming an unpatterned hard mask layer over a plurality of gate electrodes provided on an upper surface of a semiconductor substrate, forming an insulating material layer on the unpatterned hard mask layer, wherein the insulating material layer has a thickness which is substantially greater than the minimum feature size F, and patterning the unpatterned mask layer so as to form a plurality of masking strips extending along one of a parallel and a transverse direction relative to the gate electrodes such that the masking pattern is formed over the semiconductor device structure, wherein the plurality of masking strips has a width dimension which is substantially smaller than the minimum feature size F. Herein, the unpatterned hard mask layer is patterned by forming a dummy pattern on the unpatterned hard mask layer, comprising patterning the insulating material layer, wherein the dummy pattern has at least one recess, forming a first sidewall spacer structure adjacent to sidewalls of the at least one recess by depositing a polysilicon layer on the dummy pattern and anisotropically etching the polysilicon layer, wherein a first width dimension of the first sidewall spacer structure is smaller than half a width of the recess, removing the dummy pattern while maintaining the first sidewall spacer structure over the unpatterned mask layer, forming a second sidewall spacer structure with a second width dimension on the first sidewall spacer structure by depositing a nitride layer on the first sidewall spacer structure and anisotropically etching the nitride layer, wherein the second width dimension is smaller than half the width of the recess, removing the first sidewall spacer structure by selectively etching the first sidewall spacer structure such that the second sidewall spacer structure is maintained over the unpatterned mask layer, and etching the unpatterned mask layer in alignment with the second sidewall spacer structure.

In accordance with a third aspect of the present disclosure, a semiconductor device structure is provided. In accordance with some illustrative embodiments herein, the semiconductor device structure includes at least one gate electrode disposed on an upper surface of a semiconductor substrate, and a plurality of source contacts and a plurality of drain contacts formed on respective source and drain regions aligned to the at least one gate electrode, wherein a first separation between two neighboring source contacts of the plurality of source contacts is smaller than about 24 nm and a second separation between two neighboring drain contacts of the plurality of drain contacts is smaller than about 24 nm.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1j schematically illustrate a method of forming a masking pattern in accordance with some illustrative embodiments of the present disclosure;

FIGS. 2a-2d schematically illustrate a formation of source/drain contacts in accordance with some illustrative embodiments of the present disclosure; and

FIGS. 3a-3d schematically illustrate a formation of source/drain contacts in accordance with some other illustrative embodiments of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure relates to a method of forming a semiconductor device and to semiconductor devices, wherein the semiconductor devices are integrated on or in a chip. In accordance with some illustrative embodiments of the present disclosure, the semiconductor devices may substantially represent FETs, e.g., MOSFETs or MOS devices. When referring to MOS devices, the person skilled in the art will appreciate that, although the expression “MOS device” is used, no limitation to a metal-containing gate material and/or to an oxide-containing gate dielectric material is intended.

Semiconductor devices of the present disclosure concern devices which are fabricated by using advanced technologies, i.e., the semiconductor devices are fabricated by technologies applied to approach technology nodes smaller than 100 nm, for example, smaller than 50 nm or smaller than 35 nm. The person skilled in the art will appreciate that, according to the present disclosure, ground rules smaller or equal to 45 nm may be imposed. The person skilled in the art will appreciate that the present disclosure proposes semiconductor devices with structures of minimal length dimensions and/or width dimensions smaller than 100 nm, for example, smaller than 50 nm or smaller than 35 nm. For example, the present disclosure may provide semiconductor devices fabricated by using 45 nm technologies or below, e.g., 28 nm or even below.

The person skilled in the art will appreciate that semiconductor devices may be fabricated as P-channel MOS transistors or PMOS transistors and N-channel transistors or NMOS transistors; both types of transistors may be fabricated with or without mobility-enhancing stressor features or strain-inducing features. It is noted that a circuit designer can mix and match device types, using PMOS and NMOS devices, stressed and unstressed, to take advantage of the best characteristics of each device type as they best suit the semiconductor device under design.

In the following, various illustrative embodiments of the present disclosure will be explicitly described with regard to the enclosed figures, wherein a masking pattern of sub-nominal spacings is formed over an upper surface of a substrate.

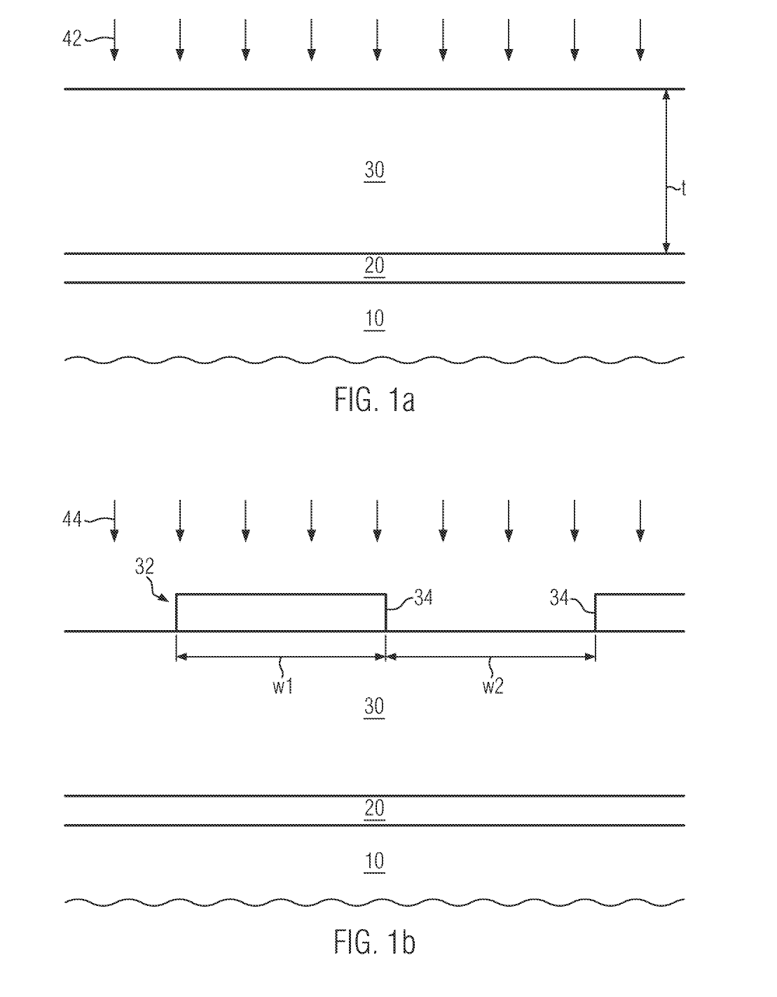

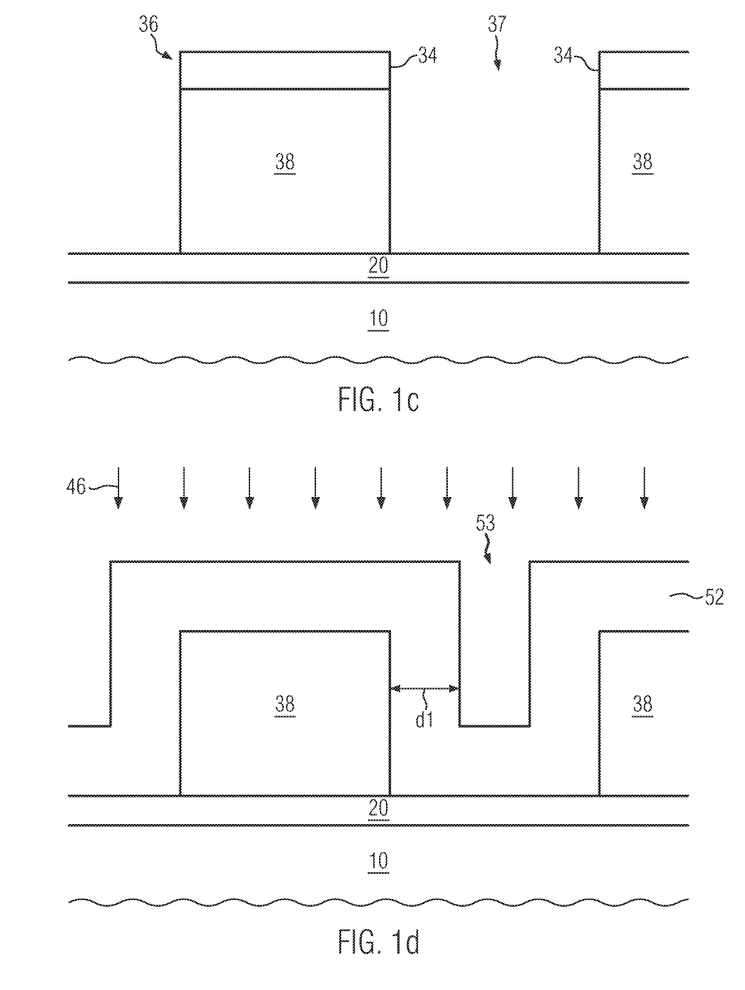

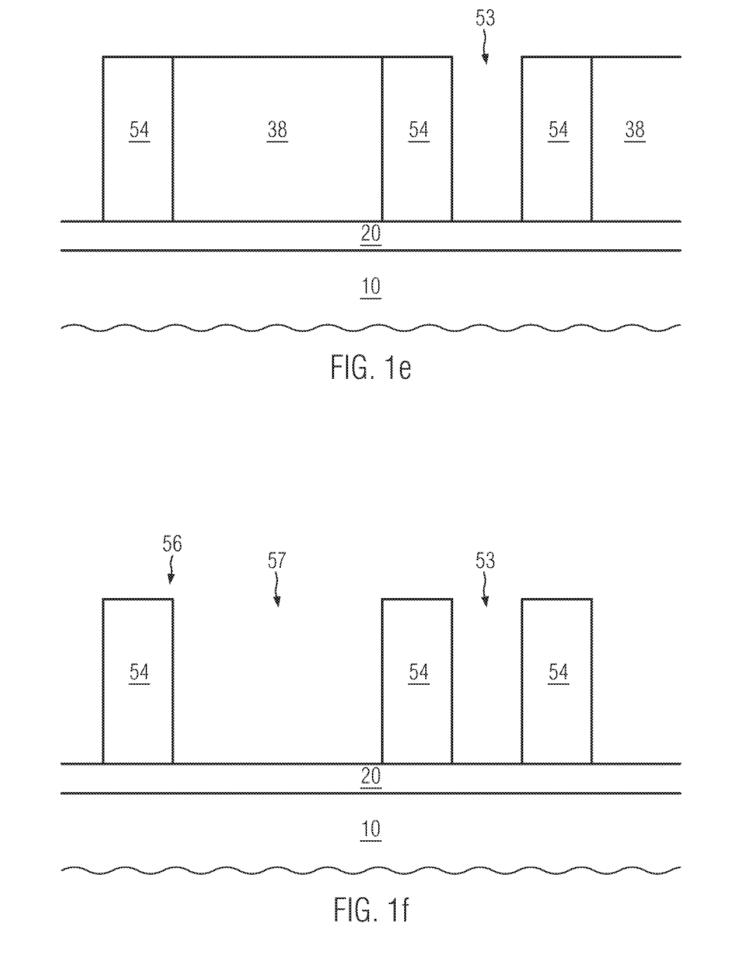

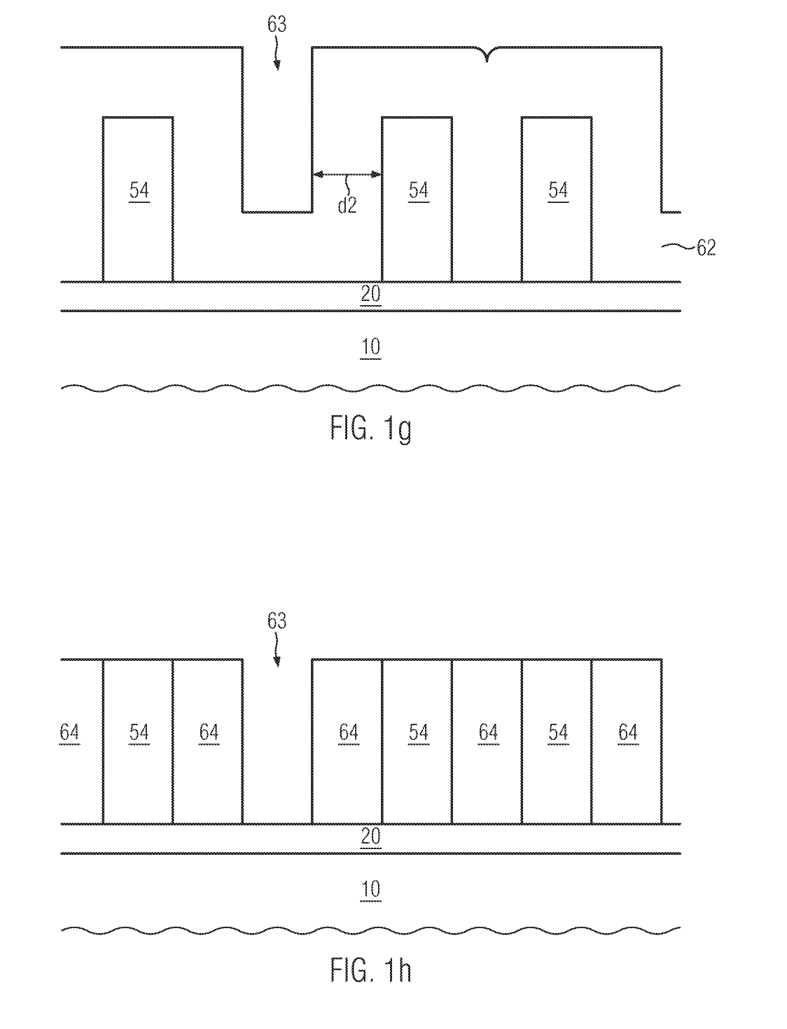

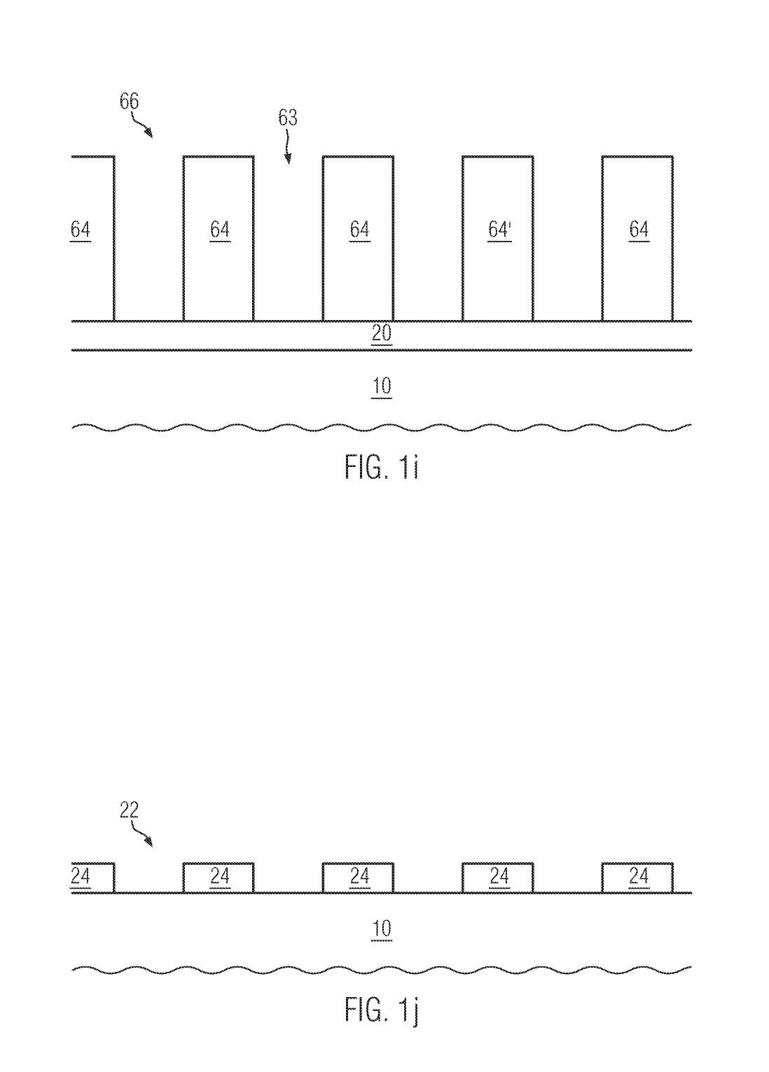

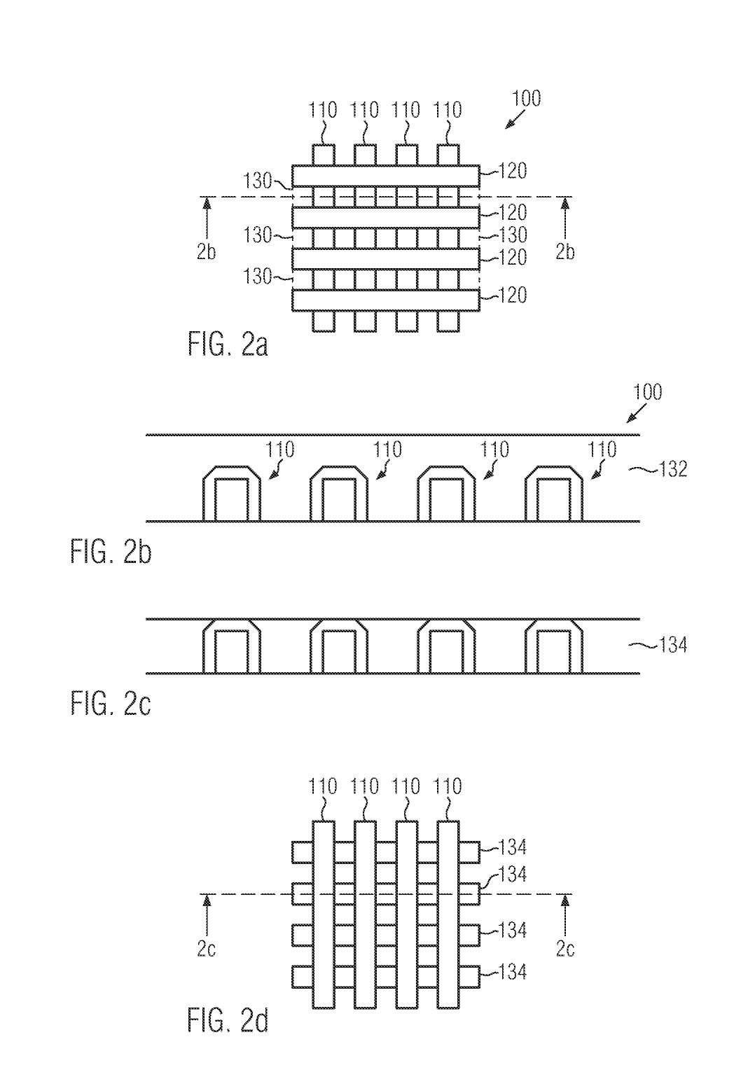

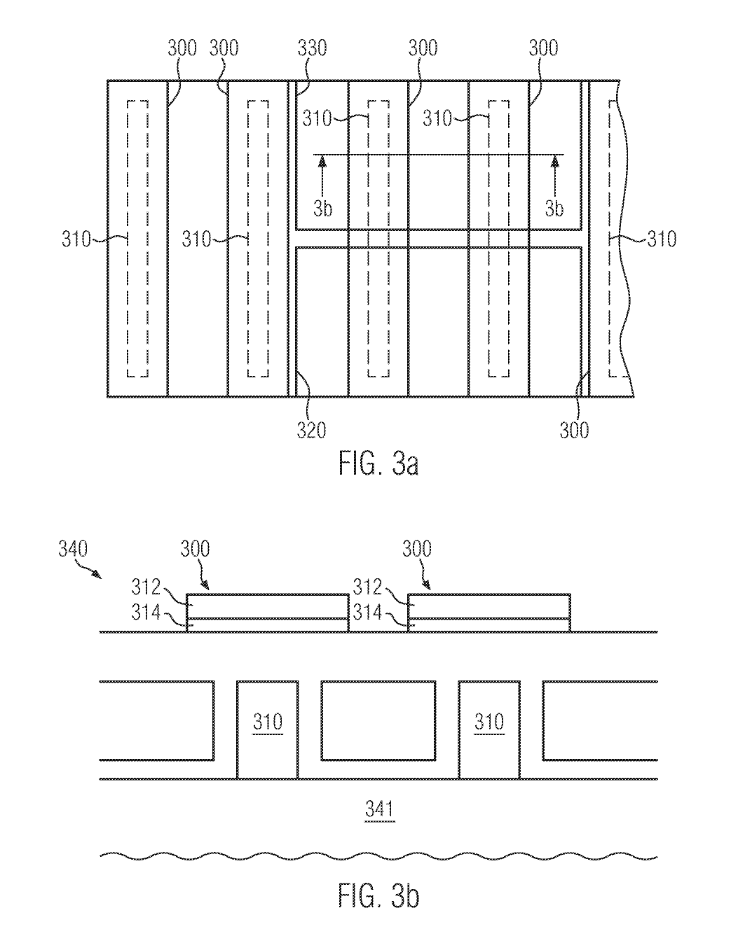

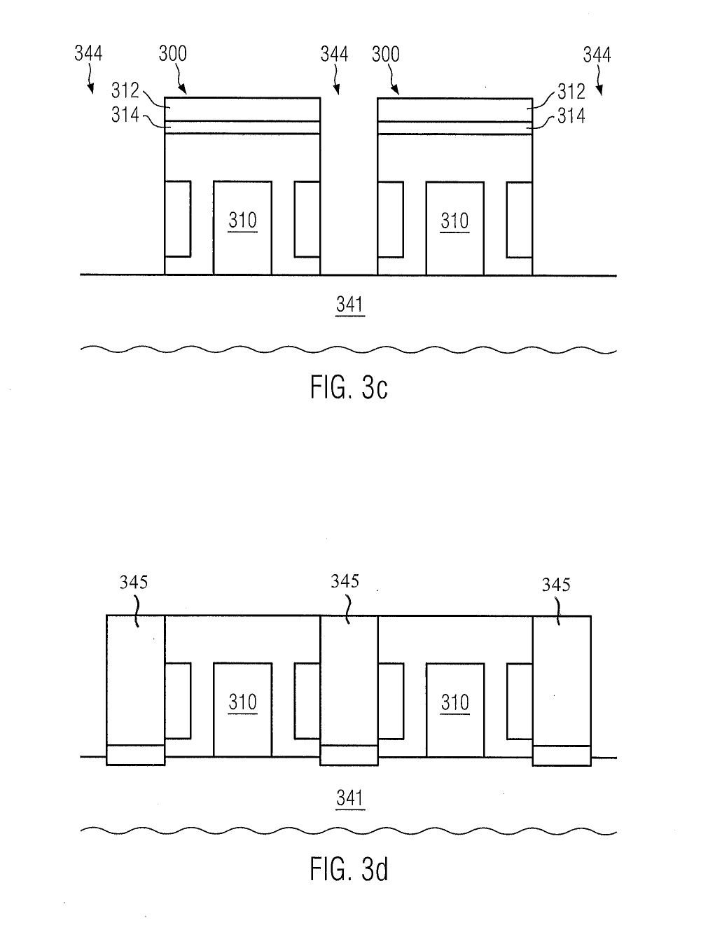

FIG. 1a schematically illustrates, in a cross-sectional view, a semiconductor device structure 10 including a semiconductor substrate (not illustrated), optionally, with a gate electrode structure (not illustrated) embedded into an interlayer dielectric (ILD) material (not illustrated) formed over the semiconductor substrate. Some illustrative examples of the semiconductor device structure 10 will be described below in greater detail with regard to FIGS. 2a-2d and 3a-3d. The semiconductor substrate may be a semiconductor bulk substrate or a semiconductor-on-insulator (SOI) substrate or a silicon/germanium-on-insulator (SGOI) substrate. In general, the terms “substrate,” “semiconductor substrate” or “semiconducting substrate” should be understood as to cover all semiconductor materials, in all forms of such semiconductor materials, and no limitation to a special kind of substrate is intended. The person skilled in the art will appreciate that, in some illustrative embodiments, the substrate may represent an SOI substrate configuration including a thin silicon film (not illustrated) disposed on a buried oxide or BOX layer (not illustrated), which in turn is formed on a substrate base or base wafer (not illustrated).

With regard to FIG. 1a, fabrication of a semiconductor device structure is schematically depicted at an early stage during fabrication, at which stage a masking pattern is to be formed over the semiconductor device structure 10. At the stage depicted in FIG. 1a, an unpatterned mask layer 20 is formed over the semiconductor device structure 10 and an insulating material layer 30 is formed on the unpatterned mask layer 20. In accordance with some illustrative examples herein, the insulating material layer 30 may comprise an oxide layer, e.g., silicon oxide, and may have a thickness t of about 24 nm or more. In accordance with some illustrative embodiments, the mask layer 20 may comprise one of a carbon material and an SiON material and a TiN material.

In accordance with illustrative embodiments of the present disclosure, a patterning process for patterning the insulating material layer 30 is described, wherein a dummy pattern (see reference numeral 36 in FIG. 1c) having a minimum size that is substantially smaller than a minimum feature size to be reached by lithography techniques is formed from the insulating material layer 30 on the unpatterned mask layer 20 and, on the basis of the dummy pattern (see FIG. 1c), a much finer masking pattern is fabricated (see FIG. 1j). Herein the minimum feature size to be reached by photolithography techniques is the minimum feature size which may be reached by known lithography techniques and/or employing known lithography tools. In accordance with some explicit examples herein, the minimum feature size that may be reached by known lithography techniques and/or employing known lithography tools may be smaller than about 24 nm.

According to FIG. 1a, the dummy pattern is formed by performing a first process sequence 42 for depositing a dummy mask material (not illustrated) on the insulating material 30 and patterning the deposited dummy mask material (not illustrated) on the insulating material layer 30 to obtain an auxiliary pattern 32 as illustrated in FIG. 1b. The auxiliary pattern 32 is used for patterning the insulating material layer 30, as will be described below in greater detail. In accordance with some illustrative examples, the first process sequence 42 may comprise depositing a carbon comprising material layer and lithographically patterning the deposited carbon comprising material layer so as to form a carbon hard mask 32 on the insulating material layer 30.

Referring to FIG. 1b, the auxiliary pattern 32 is formed by auxiliary mask portions 34 having a width w1 and a spacing w2. In accordance with some illustrative embodiments, at least one of the width w1 and the spacing w2 may represent a nominal feature size and may, in accordance with some special examples, be identified with the smallest printable size available when using a given litho equipment (not shown). In accordance with some illustrative examples of the present disclosure, at least one of the widths w1 and w2 may be of about 24 nm or more. In some special examples herein, the widths w1 and the width w2 may be substantially of equal size, although this does not pose any limitation to the present disclosure. Additionally or alternatively, the thickness t of the insulating material layer 30 may be about three times larger than at least one of the widths w1 and w2, i.e., the thickness t of the insulating material 30 may be chosen in dependence on one of the width w1 and the width w2.

Next, as illustrated in FIG. 1b, the patterning of the insulating material layer 30 is continued by a second process sequence 44 comprising an etching of the insulating material layer 30 in accordance with the auxiliary pattern 32 to result in the dummy pattern 36 as illustrated in FIG. 1c. In accordance with an illustrative example herein, the second process sequence 44 may comprise an anisotropic etch step for anisotropically etching the insulating material 30, using the unpatterned mask layer 20 as an etch stop.

Referring to FIG. 1c, the dummy pattern 36 comprises dummy mask portions 38 formed by portions of the insulating material layer 30, and one or more recesses 37. The person skilled in the art will appreciate that a width of the dummy mask portions 38 is substantially equal to the width w1, while a width of the trench 37 is substantially equal to the width w2.

Subsequent to the second process step 44, or alternatively as a part of the second process step 44, the auxiliary mask portions 34 are stripped off.

Referring to FIG. 1d, a more advanced stage during fabrication is schematically illustrated, wherein a first sidewall spacer material layer 52 is formed over the unpatterned mask layer 20 and the dummy pattern 36 which is provided by the dummy mask portions 38. In accordance with some illustrative embodiments of the present disclosure, the first sidewall spacer forming material layer 52 may be conformally deposited over the unpatterned mask layer 20 and the dummy pattern 36, e.g., by conformally depositing a polysilicon material for forming a polysilicon layer. In accordance with some illustrative examples, the first sidewall spacer forming material layer 52 may have a thickness d1 which is substantially smaller than half of the width w2. Accordingly, in depositing the first sidewall spacer forming material layer 52, sidewalls of the one or more recesses 37 of the dummy pattern 36 are covered such that one or more trenches 53 is formed in the deposited first sidewall spacer forming material layer 52 in alignment with the one or more recesses 37, the one or more trenches 53 having a width of (w2−2*d1). In accordance with a special illustrative example herein, the thickness d1 may be equal to about one third of the width w1 and/or one third of the width w2.

Subsequently, an etching process 46 may be performed for anisotropically etching the first sidewall spacer forming material layer 52 so as to form a plurality of first sidewall spacers 54 for forming a first sidewall spacer structure (see reference numeral 56 in FIG. 1f), the first sidewall spacers 54 being disposed adjacent to the dummy mask portions 38 and, particularly, adjacent to the sidewalls of the one or more recesses 37 (FIG. 1c). In accordance with some illustrative embodiments of the present disclosure, the unpatterned hard mask layer 20 is used as an etch stop during the etching process 46. The person skilled in the art will appreciate that the dummy pattern 36 (i.e. the dummy mask portions 38) is removed relative to the first sidewall spacer structure 56 such that the plurality of first sidewall spacers 54 remain on the unpatterned mask layer 20.

In accordance with some illustrative embodiments of the present disclosure, the dummy pattern may be removed by a wet etch step (not illustrated) which is configured for selectively removing the insulating material of the dummy mask portions 38 relative to the material of the side plurality of first sidewall spacers 54. In some explicit examples herein, the dummy pattern 36 may be removed by a wet removal of oxide material using DHF which is highly selective to silicon material and TiN in case that the first sidewall spacer structure 56 is formed by an oxide material, while the dummy pattern 36 is provided by a silicon material, whereas the unpatterned mask layer 20 is formed by TiN.

Referring to FIG. 1f, a more advanced stage during fabrication is illustrated, particularly after the etching process 46 is completed and the dummy pattern 36 is removed. As a result of the removal of the dummy pattern 36, one or more trenches 57 having a width equal to the width w1 are formed between each two first sidewall spacers 54 that were separated by a dummy mask portion 38 (see FIG. 1e versus FIG. 1f).

Referring to FIG. 1g, a more advanced stage during fabrication is illustrated, particularly after a second sidewall spacer forming material layer 62 is deposited over the first sidewall spacer structure 56. In accordance with some illustrative embodiments of the present disclosure, the second sidewall spacer structure forming material layer 62 is formed by highly conformally depositing the second sidewall spacer structure forming material, e.g., a nitride material, such as silicon nitride, for example, for forming a nitride layer in some illustrative examples. In accordance with some special examples herein, the thickness d2 may be smaller than half of the width w1, e.g., the thickness d2 may be equal to about one third of the width w1. However, this does not pose any limitation to the present disclosure and the person skilled in the art will appreciate that the thickness d2 may be only confined to be smaller than half of the width w1. Accordingly, one or more trenches 63 are formed in the second sidewall spacer structure forming material layer 62 in alignment with the one or more trenches 57, while the one or more trenches 53 (FIG. 1f) are substantially overfilled. The person skilled in the art will appreciate that, at this stage during fabrication, i.e., after the second sidewall spacer forming material layer 62 is deposited, only the one or more trenches 63 are present.

In accordance with some illustrative embodiments of the present disclosure, the second sidewall spacer forming material layer 62 is subsequently exposed to an anisotropic etch step (not illustrated) for anisotropically etching the second sidewall spacer forming material layer 62 such that a second sidewall spacer structure 66 (see FIG. 1i) having a plurality of second sidewall spacers 64 is formed, as it illustrated in FIG. 1h. In accordance with some illustrative examples herein, the second sidewall spacer forming material layer 62 may be etched by means of an reactive ion etch (RIE) process.

Subsequently to forming the second sidewall spacer structure 66, the first sidewall spacer structure 56 may be removed by a wet etch process, wherein the first sidewall spacer structure 56 is selectively etched relative to the second sidewall spacer structure 66, where the unpatterned mask layer 20 is used as an etch stop. In accordance with an explicit example herein, the wet etch step may comprise one of TMAH and ammonia.

Referring to FIG. 1i, a more advanced stage during fabrication is illustrated, particularly after the first sidewall spacer 56 structure is removed. At this stage, only the second sidewall spacer structure 66 remains on the unpatterned mask layer 20. The person skilled in the art will appreciate that the dimensions of the second sidewall spacer structure 66, particularly a width of the individual spacers 64 and a separation between two neighboring spacers 64, depends on the widths w1, w2 and the thicknesses d1, d2. For example, a width of the one or more trenches 63 is substantially equal to (w1−2*d2). Furthermore, a width of the second sidewall spacer 64′ is substantially equal to (w2−2*d1). Therefore, the width of the second sidewall spacer 64 is substantially defined by the thickness d2, whereas the spacing between two neighboring second sidewall spacers 64 and between the second sidewall spacer 64′ and its neighboring second sidewall spacer 64, unless the width of the trench 63, is substantially equal to the thickness d1. In the special case of the widths w1 and w2 being substantially of equal size (that is the widths w1 and w2 are of an equal size w: w1=w2=w, where w is for example of about 24 nm or more) and the thicknesses d1 and d2 being equal to one third of the width w (that is d1=d3=w/3), a regular pattern of sidewall spacer 64 having a width of one third of the width w (w/3) and being separated by a distance equal to one third of the width w (w/3) is obtained above the unpatterned mask layer 20. Provided that w is about 24 nm, for example, a structure (that is the second sidewall spacer structure 66) having dimensions of about 8 nm may be formed.

Next, an anisotropic etch step (not illustrated) is performed, e.g., an RIE etch step, to open the unpatterned mask layer 20 in accordance with the second spacer structure 66 and, after the second spacer structure 66 is removed, a masking pattern 22 formed by masking strips 24 is obtained over the semiconductor device structure 10, as shown in FIG. 1j, that is the patterning of the unpatterned mask layer 20 as completed. The person skilled in the art will appreciate that, in accordance with some examples, in which the second sidewall spacer structure 66 is formed by nitride material, e.g., SiN, hot phosphoric acid may be used to remove the second sidewall spacer structure 66.

With regard to some illustrative applications of the above described patterning technique, the person skilled in the art will appreciate that the afore described patterning of the unpatterned mask layer 20 may be applicable to equal line space patterns, for example for memory arrays, such as SRAM/DRAM.

With regard to FIGS. 2a-2d, an illustrative application of the above-described patterning technique is described in more detail. FIG. 2a schematically illustrates, in a top view, a semiconductor device structure 100 having a plurality of gate electrodes 110 and a masking pattern 120 formed over the plurality of gate electrodes 110. The masking pattern 120 comprises a plurality of masking strips which extend along a transverse direction relative to the gate electrodes 110 and are separated by trenches 130. The person skilled in the art will appreciate that the masking strips 120 may be formed in accordance with the above-described technique to obtain the masking strips 24 of the masking pattern 22 in FIG. 1j.

Subsequent to forming the masking pattern 120, the trenches 130 between the masking strips 120 are subsequently filled with a contact forming material, e.g., tungsten (W), as indicated by the broken lines in FIG. 2a.

Referring to FIG. 2b, a cross-section along the line 2b-2b in FIG. 2a is schematically illustrated. FIG. 2b illustrates a more advanced stage during fabrication, particularly after the trenches 130 between the masking strips 120 are filled with a contact forming material 132.

Next, the masking strips 120 are removed and the contact forming material 132 is polished down to the gate electrodes 110, for example, using the gate electrodes 110 as an indicator for the end of the polishing process, such that the gate electrodes 110 separate the contact forming material 132 in FIG. 2b into individual contacts 134, as illustrated in FIG. 2c. Accordingly, source/drain regions (not illustrated) may be contacted by the contacts 134.

With regard to FIG. 2d, a top view corresponding to the cross-section illustrated in FIG. 2c is schematically depicted, wherein the cross-section illustrated in FIG. 2c is taken along the line 2c-2c as indicated in FIG. 2d.

With regard to FIGS. 3a-3d, a further illustrative application of the patterning technique as described above with regard FIGS. 1a-1j is schematically illustrated. Herein, in accordance with the illustrative embodiments depicted in FIGS. 3a-3d, a block-and-line-grid approach (alike to the 20 LP approach) is performed, where contact lines are fabricated using the patterning technique as described with regard to FIGS. 1a-1j above.

Referring to FIG. 3a, a top view of a first masking pattern 300 comprising masking strips fabricated in accordance with the technique as described above with regard to FIGS. 1a-1j is schematically illustrated, wherein the masking strips of the first masking pattern 300 cover gate electrodes 310. Furthermore, a second masking pattern is provided over the first masking pattern 300, the second masking pattern comprising two windows 320, 330 which partially expose the first masking pattern 300, i.e., the first masking pattern 300 is partially exposed through the windows 320, 330 of the second masking pattern.

FIG. 3b schematically illustrates, in a cross-sectional view along the line 3b-3b in FIG. 3a, a semiconductor device structure 340 comprising the gate electrodes 310 and source/drain regions formed in a substrate 341 underlying the gate electrodes 310. In accordance with some illustrative embodiments, the first masking pattern 300 may be formed as a two layered mask comprising a TiN layer 312 and an oxide layer 314. The person skilled in the art will appreciate that this does not impose any limitation to the present disclosure with regard to the material and the configuration of the first masking pattern 300.

Next, as illustrated in FIG. 3c, contact trenches 344 may be etched in alignment with the first masking pattern 300, the contact trenches 344 ending on an upper surface of the substrate 341.

Next, a contact structure 345 comprising silicide regions and contacts, e.g., formed by tungsten (W), may be formed within the contact trenches 344 in accordance with conventional techniques, resulting in the semiconductor device structure 340 as illustrated in FIG. 3d.

The person skilled in the art will appreciate that, in accordance with the application illustrated in FIGS. 3a-3d, small trenches, e.g., 20 nm and less, may be defined by a first patterning step which may apply a patterning technique as explained above with regard to FIGS. 1a-1j. However, a critical dimension of the small trenches can be made much smaller and much more accurate than for known contact holes when employing the technique for forming a masking pattern in accordance with the present disclosure. The trenches may then be transferred into an unpatterned hard mask to result in the first masking pattern 300 as illustrated in FIG. 3a.

In a second lithographical step, one or more large windows, e.g., the windows 320 and 330 in FIG. 3a, may be formed. By means of the large windows and the first masking pattern, TS contacts may be patterned and formed for contacting source/drain regions.

The person skilled in the art will appreciate that the present disclosure provides, in various aspects, for an enabler for a half pitch patterning down to dimensions of about 24 nm and less, e.g., 8 nm. The person skilled in the art will appreciate that the techniques as proposed by the present disclosure allow for a lowering of costs for exposure tools.

In some aspects of the present disclosure, a smart spacer technique is used for patterning half pitches that are three times smaller than smallest printable sizes. The person skilled in the art will appreciate that the disclosed techniques allow for an extension of the usage of lower resolution litho equipment at vary small scales.

In accordance with some aspects of the present disclosure, a pitch fragmentation process (i.e., the patterning process as described above with regard to FIGS. 1a-1j) may be performed for patterning a mask over a semiconductor device structure, wherein the pitch fragmentation process may be performed on top of a hard mask, e.g., a hard mask formed from one of aC, SiON and TiN. Then, the sub-nominal lines/spacers may be transferred into the underlying hard mask.

In accordance with some applications of the present disclosure, this technique allows patterning of gates in memory arrays with a resolution of F/3, where F denotes a nominal feature size such as a minimum feature size that may be reached by known lithography techniques and/or known lithography tools, e.g., about 24 nm or less. In some illustrative examples, contacts can be patterned by using the techniques as presented by the present disclosure and a 20 LP like approach may be performed to create a block-and-line mask for forming long hole contacts.

The explicit embodiments as described above employ forming two sidewall spacer structures when patterning the unpatterned mask layer over the semiconductor device structure. This does not pose any limitation on the present disclosure and the person skilled in the art will appreciate that more than two sidewall spacers may be formed instead. For example, a third sidewall spacer structure may be formed subsequent to forming the second sidewall spacer structure and before patterning the unpatterned mask layer, the third sidewall spacer having a third width which is substantially smaller than half of a width of recesses defined by the second sidewall spacer structure. Herein, the third sidewall spacer structure is formed adjacent to the second sidewall spacer structure so as to iterate the step of forming the second sidewall spacer structure adjacent to the first sidewall spacer structure.

In summary, the present disclosure provides for methods of forming a masking pattern and a semiconductor device structure, wherein printed half pitches having dimensions which are substantially smaller than a minimum feature size that may be reached by known lithography techniques and/or known lithography tools may be formed, such as, for example, of about 24 nm or less. In accordance with a first aspect of the present disclosure, a method of forming a masking pattern is provided, wherein an unpatterned mask layer is formed over a semiconductor device structure provided in and on an upper surface of a semiconductor substrate, and the unpatterned mask layer is patterned for forming the masking pattern over the semiconductor device structure. Herein, the unpatterned mask layer is patterned by forming a dummy pattern on the unpatterned mask layer, wherein the dummy pattern has at least one recess, forming a first sidewall spacer structure adjacent to sidewalls of the at least one recess, wherein a first width dimension of the first sidewall spacer structure is smaller than half a width of the recess, removing the dummy pattern relative to the first sidewall spacer structure, forming a second sidewall spacer structure on the first sidewall spacer structure, wherein a second width dimension of the first sidewall spacer structure is smaller than half the width of the recess, removing the first sidewall spacer structure relative to the second sidewall spacer structure, and etching the unpatterned mask layer in alignment with the second sidewall spacer structure.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed:

1. A method of forming a masking pattern, comprising:
forming an unpatterned mask layer over a semiconductor device structure provided in and on an upper surface of a semiconductor substrate;
patterning said unpatterned mask layer for forming said masking pattern over said semiconductor device structure, said patterning comprising:
forming a dummy pattern on said unpatterned mask layer, said dummy pattern having at least one recess;
forming a first sidewall spacer structure adjacent to sidewalls of said at least one recess, wherein a first width dimension of said first sidewall spacer structure is smaller than half a width of said recess;
removing said dummy pattern, while maintaining said first sidewall spacer structure over said unpatterned mask layer;
forming a second sidewall spacer structure on said first sidewall spacer structure, wherein a second width dimension of said second sidewall spacer structure is smaller than said half width of said recess;
removing said first sidewall spacer structure, while maintaining said second sidewall spacer structure over said unpatterned mask layer; and
etching said unpatterned mask layer in alignment with said second sidewall spacer structure.

2. The method of claim 1, wherein forming said dummy pattern comprises depositing an insulating material layer on said unpatterned mask layer and patterning said insulating material layer for forming said dummy pattern on said unpatterned mask layer.

3. The method of claim 2, wherein patterning said insulating material layer comprises depositing a carbon comprising material on said insulating material layer, lithographically patterning said carbon comprising material and selectively etching said insulating material layer in accordance with said patterned carbon comprising material.

4. The method of claim 2, wherein a thickness of said insulating material layer is substantially greater than said width of said recess, preferably between two to three times.

5. The method of claim 1, wherein said width of said recess is substantially equal to a minimum feature size (F) to be reached by photolithography techniques.

6. The method of claim 1, wherein said first sidewall spacer structure is formed by forming a polysilicon liner over said dummy pattern and anisotropically etching said polysilicon liner.

7. The method of claim 6, wherein said first sidewall spacer structure is removed by exposing said polysilicon to a wet etch process comprising one of TMAH and ammonia.

8. The method of claim 1, wherein said first and second widths are one of substantially equal to and smaller than one third of said width of said recess.

9. The method of claim 8, wherein at least one of said first and second widths is smaller than about 24 nm.

10. The method of claim 8, wherein said first width is substantially equal to said second width.

11. The method of claim 1, wherein said semiconductor device structure comprises a plurality of gate electrodes extending along one of a parallel and a transverse direction relative to said masking pattern.

12. The method of claim 1, wherein forming said unpatterned mask layer comprises depositing one of a carbon material and an SiON material and a TiN material.

13. A method of forming a masking pattern having a minimum size that is substantially smaller than a minimum feature size (F) to be reached by photolithography techniques, the method comprising:
forming an unpatterned hard mask layer over a plurality of gate electrodes provided on an upper surface of a semiconductor substrate;
forming an insulating material layer on said unpatterned hard mask layer, said insulating material layer having a thickness which is substantially greater than said minimum feature size F;
patterning said unpatterned mask layer so as to form a plurality of masking strips extending along one of a parallel and a transverse direction relative to said gate electrodes such that said masking pattern is formed over said semiconductor device structure, wherein said plurality of masking strips has a width dimension which is substantially smaller than said minimum feature size F, said patterning comprising:
forming a dummy pattern on said unpatterned hard mask layer by patterning said insulating material layer, said dummy pattern having at least one recess;
forming a first sidewall spacer structure adjacent to sidewalls of said at least one recess by depositing a polysilicon layer on said dummy pattern and anisotropically etching said polysilicon layer, wherein a first width dimension of said first sidewall spacer structure is smaller than half a width of said recess;
removing said dummy pattern, while maintaining said first sidewall spacer structure over said unpatterned mask layer;
forming a second sidewall spacer structure with a second width dimension on said first sidewall spacer structure by depositing a nitride layer on said first sidewall spacer structure and anisotropically etching said nitride layer, wherein said second width dimension is smaller said half width of said recess;
removing said first sidewall spacer structure by selectively etching said first sidewall spacer structure such that said second sidewall spacer structure is maintained over said unpatterned mask layer; and
etching said unpatterned mask layer in alignment with said second sidewall spacer structure.

14. The method of claim 13, wherein a thickness of said insulating material layer is substantially between 2 to 4 times greater than said minimum feature size F.

15. The method of claim 13, wherein said first and second widths are smaller than about 24 nm.

16. The method of claim 13, wherein at least one of said first and second widths is substantially equal to or smaller than one third of said minimum feature size F.

17. The method of claim 13, wherein said first width is substantially equal to said second width.

18. A semiconductor device structure, comprising:
at least one gate electrode disposed on an upper surface of a semiconductor substrate; and
a plurality of source contacts and a plurality of drain contacts formed on respective source and drain regions aligned to said at least one gate electrode;
wherein a first separation between two neighboring source contacts of said plurality of source contacts is smaller than about 24 nm and a second separation between two neighboring drain contacts of said plurality of drain contacts is smaller than about 24 nm.

19. The semiconductor device structure of claim 18, wherein at least one of said first and second separations is smaller than about 10 nm.

20. The semiconductor device structure of claim 18, wherein said first and said second separations are substantially equal in size.
